(19) United States
(12) Patent Application Publication
(10) Pub. No.: US 2004/0049305 A1
(43) Pub. Date: Mar. 11, 2004

(54) Audio/video transmitter apparatus and audio/video transmission system

(75) Inventors: Hiroshi Takahashi, Osaka-Shi (JP); Takeshi Morimoto, Sakai-Shi (JP)

Correspondence Address: NIXON & VANDERHYE, PC, 1100 N GLEBE ROAD, 8TH FLOOR, ARLINGTON, VA, 22201-4714, US

(73) Assignee: Sharp Kabushiki Kaisha, Osaka (JP)

(21) Appl. No.: 10/655,032

(22) Filed: Sep. 5, 2003

(30) Foreign Application Priority Data
Sep. 11, 2002 (JP) 2002-265022

(51) Int. Cl. G06F 17/00; H03G 7/00

(52) U.S. Cl. 700/94; 381/106

(57) ABSTRACT

A conventional audio/video transmission system including an audio/video transmitter apparatus and an audio/video receiver apparatus suffers from delay of video relative to audio resulting from reproducing audio from the audio signal output from the audio/video transmitter apparatus and reproducing video from the video signal output from the audio/video receiver apparatus. To solve this inconvenience, according to the invention, in an audio/video transmission system including an audio/video transmitter apparatus and an audio/video receiver apparatus, the audio/video transmitter apparatus additionally has an audio delay circuit that outputs the input analog audio signal with a predetermined delay time.

### BACKGROUND OF THE INVENTION

1. Field of the Invention

The present invention relates to an audio/video transmission system for transmitting audio and video signals on a wireless basis.

2. Description of the Prior Art

FIG. 8 shows an example of the configuration of a conventional audio/video transmission system for transmitting audio and video signals on a wireless basis. The audio/video transmission system shown in FIG. 8 includes an audio/video transmitter apparatus 100 and an audio/video receiver apparatus 200.

First, the circuit configuration of the audio/video transmitter apparatus 100 will be described. The audio/video transmitter apparatus 100 includes a video input terminal 1, an audio input terminal 2, an audio output terminal 3, a video A/D converter circuit 4, a data compression circuit 5, a wireless transmitter circuit 6, an antenna terminal 7, an audio A/D converter circuit 9, and a power supply circuit 10.

The video input terminal 1 is connected to the input end of the video A/D converter circuit 4. The output end of the video A/D converter circuit 4 is connected to one input end of the data compression circuit 5. The audio input terminal 2 is connected to the input end of the audio A/D converter circuit 9 and to the audio output terminal 3. The output end of the audio A/D converter circuit 9 is connected to the other input end of the data compression circuit 5. The output end of the data compression circuit 5 is connected to the input end of the wireless transmitter circuit 6, and the output end of the wireless transmitter circuit 6 is connected to the antenna terminal 7. The power supply circuit 10 is connected to each of the video A/D converter circuit 4, data compression circuit 5, wireless transmitter circuit 6, and audio A/D converter circuit 9. Moreover, an antenna 8 is externally fitted to the audio/video transmitter apparatus 100. Specifically, the antenna 8 is connected to the antenna terminal 7.

Next, the circuit configuration of the audio/video receiver apparatus 200 will be described. The audio/video receiver apparatus 200 includes an antenna terminal 22, a wireless receiver circuit 23, a data decompression circuit 24, a video D/A converter circuit 25, a video output terminal 26, an audio D/A converter circuit 27, an audio output terminal 28, and a power supply circuit 29.

The antenna terminal 22 is connected to the input end of the wireless receiver circuit 23. The output end of the wireless receiver circuit 23 is connected to the input end of the data decompression circuit 24. One output end of the data decompression circuit 24 is connected to the input end of the video D/A converter circuit 25, and the other output end of the data decompression circuit 24 is connected to the input end of the audio D/A converter circuit 27. The output end of the video D/A converter circuit 25 is connected to the video output terminal 26, and the output end of the audio D/A converter circuit 27 is connected to the audio output terminal 28. The power supply circuit 29 is connected to each of the wireless receiver circuit 23, data decompression circuit 24, video D/A converter circuit 25, and audio D/A converter circuit 27. Moreover, an antenna 21 is externally fitted to the audio/video receiver apparatus 200. Specifically, the antenna 21 is connected to the antenna terminal 22.

Next, the operation of the audio/video transmission system shown in FIG. 8 will be described. First, the operation of the audio/video transmitter apparatus 100 will be described. An alternating-current voltage fed from outside is converted by the power supply circuit 10 into a predetermined direct-current voltage (+B), which is fed to each of the video A/D converter circuit 4, data compression circuit 5, wireless transmitter circuit 6, and audio A/D converter circuit 9.

The video input terminal 1 and audio input terminal 2 are connected to a video playback apparatus such as a videocassette recorder (not illustrated). An analog video signal A_{V1} from the video playback apparatus is fed in via the video input terminal 1, and is converted into a digital video signal D_{V1} by the video A/D converter circuit 4.

On the other hand, an analog audio signal A_{A1} from the video playback apparatus is fed in via the audio input terminal 2, and is split into two signals, of which one is converted into a digital audio signal D_{A1} by the audio A/D converter circuit 9, and of which the other is directly fed out via the audio output terminal 3.

The digital video signal D_{V1} and digital audio signal D_{A1} are subjected to data compression performed by the data compression circuit 5, and are thereby converted into a compressed audio/video signal C_{AV1}. The compressed audio/video signal C_{AV1} is modulated into a radio-frequency signal (having 2.4 GHz, for example) by the wireless transmitter circuit 6, and is then transmitted in the form of a radio wave from the antenna 8.

Next, the operation of the audio/video receiver apparatus 200 will be described. An alternating-current voltage fed from outside is converted by the power supply circuit 29 into a predetermined direct-current voltage (+B), which is fed to each of the wireless receiver circuit 23, data decompression circuit 24, video D/A converter circuit 25, and audio D/A converter circuit 27.

The radio wave transmitted from the antenna 8 is received by the antenna 21, and the thus received radio-frequency signal is demodulated by the wireless receiver circuit 23 into a compressed audio/video signal C_{AV2}, which is identical with the compressed audio/video signal C_{AV1}. The compressed audio/video signal C_{AV2} is decompressed by the data decompression circuit 24, and is thereby converted into a digital video signal D_{V2} and a digital audio signal D_{A2}, which are identical with the digital video signal D_{V1} and digital audio signal D_{A1}, respectively.

The digital video signal D_{V2} is converted by the video D/A converter circuit 25 into an analog video signal A_{V2}, which is identical with the analog video signal A_{V1}, and is then fed out via the video output terminal 26. The digital audio signal D_{A2} is converted by the audio D/A converter circuit 27 into an analog audio signal A_{A2}, which is identical with the analog audio signal A_{A1}, and is then fed out via the audio output terminal 28.

By connecting the video output terminal 26 and audio output terminal 28 to the external input terminals of, for example, a television monitor (not illustrated), it is possible to view, on the television monitor that is connected to the audio/video receiver apparatus 200, the audio and video reproduced on the video playback apparatus, such as a videocassette recorder, that is connected to the audio/video transmitter apparatus 100.

Inconveniently, however, the audio/video transmission system shown in FIG. 8 has the following disadvantage. When the audio/video transmission system is used in such a way that video is reproduced from the analog video signal fed out via the video output terminal 26 and that audio is reproduced from the analog audio signal fed out via the audio output terminal 3, while the analog video signal fed out via the video output terminal 26 is subjected to data compression and then to data decompression before it reaches the video output terminal 26, the analog audio signal fed out via the audio output terminal 3 is not subjected to either data compression or data decompression before it reaches the audio output terminal 3. Thus, the analog video signal fed out via the video output terminal 26 is delayed by the time required to perform signal processing for data compression and data decompression relative to the analog audio signal fed out via the audio output terminal 3. That is, video is delayed relative to audio. For example, in a case where the data compression performed by the data compression circuit 5 and the data decompression performed by the data decompression circuit 24 are performed by methods complying with MPEG2, video is delayed by about one second relative to audio.

The audio/video transmission system is used in the fashion described above, for example, in a case where a liquid crystal video projector and a screen on which to project an optical image from the liquid crystal video projector are arranged so as to face each other. In this case, the audio/video transmitter apparatus 100 is placed, along with an amplifier and speakers, near the screen, and the audio/video receiver apparatus 200 is placed near the liquid crystal video projector. Then, the speakers are connected via the amplifier to the audio output terminal 3 of the audio/video transmitter apparatus 100, and the external input terminal of the liquid crystal video projector is connected to the video output terminal 26 of the audio/video receiver apparatus 200.

### SUMMARY OF THE INVENTION

An object of the present invention is to provide an audio/video transmission system including an audio/video transmitter apparatus and an audio/video receiver apparatus which is free from delay of video relative to audio even in a case where audio is reproduced from the audio signal output from the audio/video transmitter apparatus and video is reproduced from the video signal output from the audio/video receiver apparatus.

To achieve the above object, according to the present invention, an audio/video transmission system is provided with:

an audio/video transmitter apparatus;

a wireless signal transmitter for transmitting a wireless signal according to the signal output from a wireless transmitter circuit provided in the audio/video transmitter apparatus;

a wireless signal receiver for receiving the wireless signal transmitted from the wireless signal transmitter to output a signal according to the received wireless signal;

and an audio/video receiver apparatus including:

a wireless receiver circuit for demodulating the signal output from the wireless signal receiver to output a compressed audio/video signal; and

a data decompression circuit for performing data decompression on the compressed audio/video signal output from the wireless receiver circuit.

Here, the audio/video transmitter apparatus comprises:

a video A/D converter circuit for converting an input analog video signal into a digital video signal;

an audio A/D converter circuit for converting an input analog audio signal into a digital audio signal;

a data compression circuit for performing data compression on the digital video and audio signals;

a wireless transmitter circuit for modulating the compressed audio/video signal output from the data compression circuit; and

an audio delay circuit for outputting the input analog audio signal with a predetermined delay time.

### BRIEF DESCRIPTION OF THE DRAWINGS

This and other objects and features of the present invention will become clear from the following description, taken in conjunction with the preferred embodiments with reference to the accompanying drawings in which:

FIG. 1 is a diagram showing the configuration of the audio/video transmission system of a first embodiment of the invention;

FIG. 2 is a diagram showing the configuration of the audio/video transmitter apparatus provided in the audio/video transmission system of a second embodiment of the invention;

FIG. 3 is a flow chart showing the operation of the control circuit provided in the audio/video transmitter apparatus shown in FIG. 2;

FIG. 4 is a diagram showing the configuration of the audio/video transmitter apparatus provided in the audio/video transmission system of a third embodiment of the invention;

FIG. 5 is a flow chart showing the operation of the control circuit provided in the audio/video transmitter apparatus shown in FIG. 4;

FIG. 6 is a diagram showing the configuration of the audio/video transmitter apparatus provided in the audio/video transmission system of a fourth embodiment of the invention;

FIG. 7 is a flow chart showing the operation of the control circuit provided in the audio/video transmitter apparatus shown in FIG. 6; and

FIG. 8 is a diagram showing an example of the configuration of a conventional audio/video transmission system.

### DESCRIPTION OF THE PREFERRED EMBODIMENTS

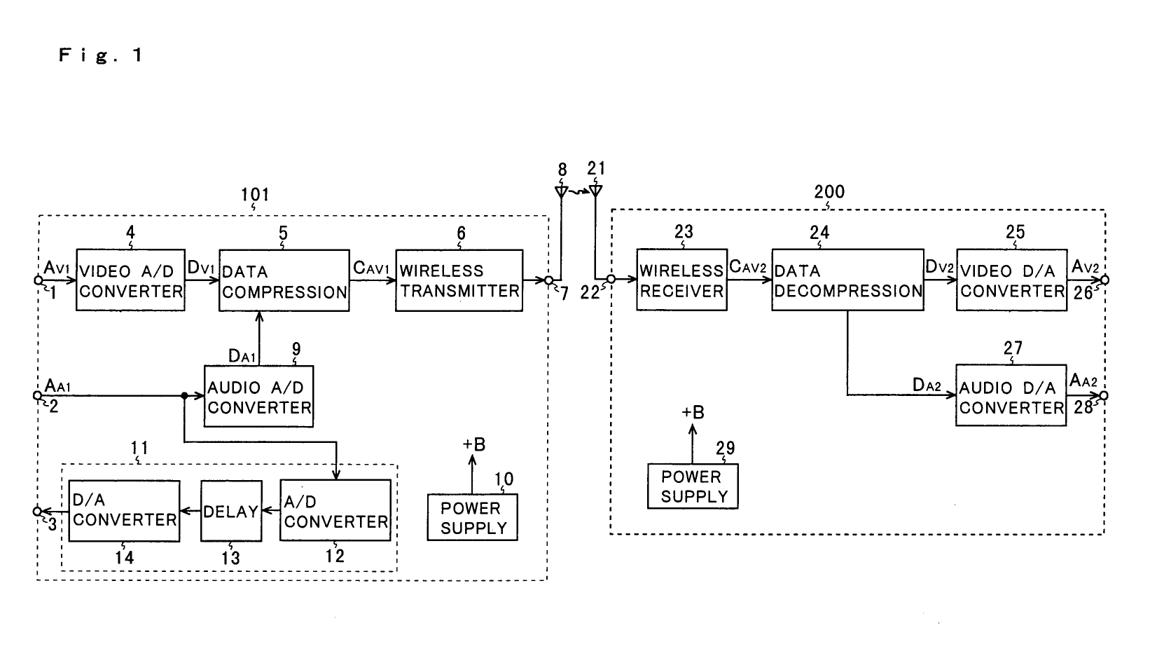

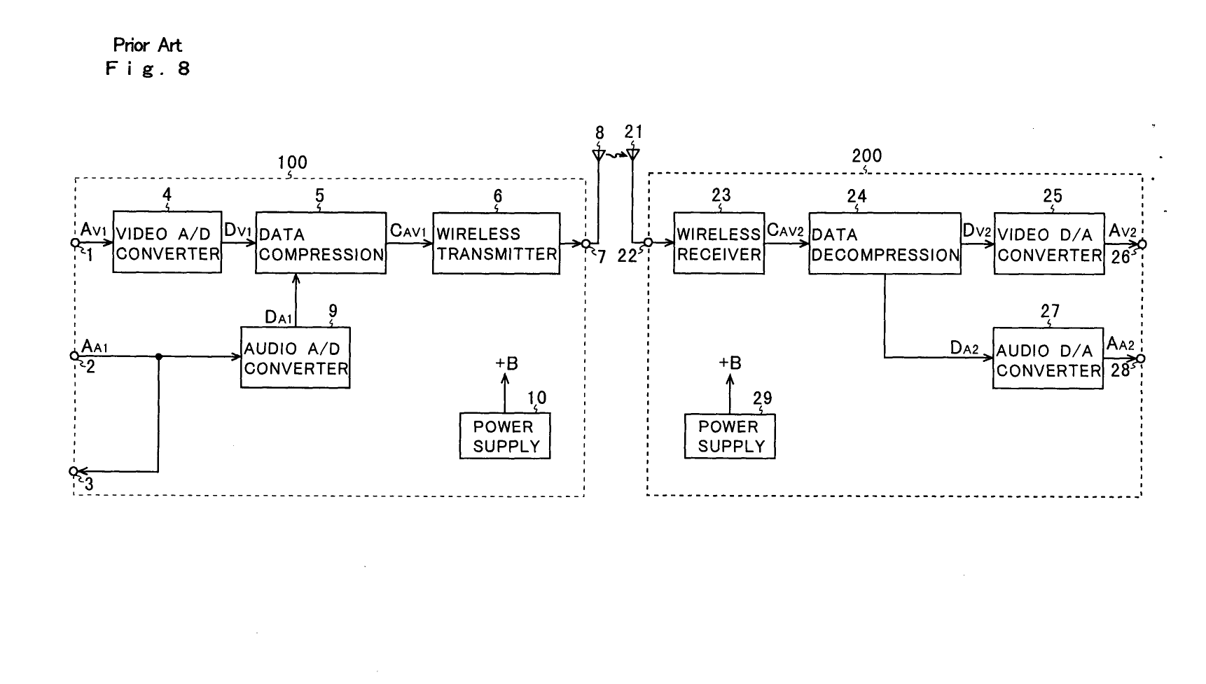

FIG. 1 shows the configuration of the audio/video transmission system of a first embodiment of the invention. In FIG. 1, such circuit blocks as are found also in FIG. 8 are identified with the same reference numerals, and their explanations will not be repeated.

The audio/video transmission system shown in FIG. 1 includes an audio/video transmitter apparatus 101, an antenna 8, an audio/video receiver apparatus 200, and an antenna 21.

As compared with the audio/video transmitter apparatus 100 provided in the audio/video transmission system shown in FIG. 8, the audio/video transmitter apparatus 101 is additionally provided with an audio delay circuit 11. The audio delay circuit 11 is composed of an A/D converter circuit 12, a delay circuit 13, and a D/A converter circuit 14.

The audio input terminal 2 is connected to the input end of the audio A/D converter circuit 9 and to the input end of the A/D converter circuit 12. The output end of the A/D converter circuit 12 is connected to the input end of the delay circuit 13, and the output end of the delay circuit 13 is connected to the input end of the D/A converter circuit 14. The output end of the D/A converter circuit 14 is connected to the audio output terminal 3.

In this configuration, an analog audio signal A_{A1} fed in via the audio input terminal 2 is split into two signals, of which one is converted by the audio A/D converter circuit 9 into a digital audio signal D_{A1}, and of which the other is converted by the A/D converter circuit 12 into a digital audio signal. The digital audio signal output from the A/D converter circuit 12 is given a predetermined delay time by the delay circuit 13, and is then converted by the D/A converter circuit 14 into an analog audio signal, which is then fed out via the audio output terminal 3. The predetermined delay time produced by the delay circuit 13 is so determined as to be substantially equal to the time required for the signal processing performed by the data compression circuit 5 and data decompression circuit 24. For example, in a case where the data compression performed by the data compression circuit 5 and the data decompression performed by the data decompression circuit 24 are performed by methods complying with MPEG2, the time required for the signal processing performed by the data compression circuit 5 and data decompression circuit 24 is about one second, and accordingly it is advisable that the predetermined delay time produced by the delay circuit 13 be set to be about one second.

When the audio/video transmission system shown in FIG. 1 is used in such a way that video is reproduced from the analog video signal A_{V2} fed out via the video output terminal 26 and that audio is reproduced from the analog audio signal fed out via the audio output terminal 3, the analog video signal A_{V2} fed out via the video output terminal 26 is subjected to data compression and then to data decompression and accordingly takes extra time before it reaches the video output terminal 26, and the analog audio signal fed out via the audio output terminal 3 is given a delay time equal to the time required to perform signal processing for data compression and data decompression before it reaches the audio output terminal 3. This makes it possible to substantially eliminate the time difference between the analog video signal A_{V2} fed out via the video output terminal 26 and the analog audio signal fed out via the audio output terminal 3. In this way, it is possible to realize an audio/video transmission system that is free from delay of video relative to audio even in a case where audio is reproduced from the audio signal output from an audio/video transmitter apparatus and video is reproduced from the video signal output from an audio/video receiver apparatus.

Here, a single A/D converter circuit may be shared as the audio A/D converter circuit 9 and A/D converter circuit 12. In that case, the output signal of the shared circuit is split into two signals, which are then fed to the data compression circuit 5 and delay circuit 13, respectively.

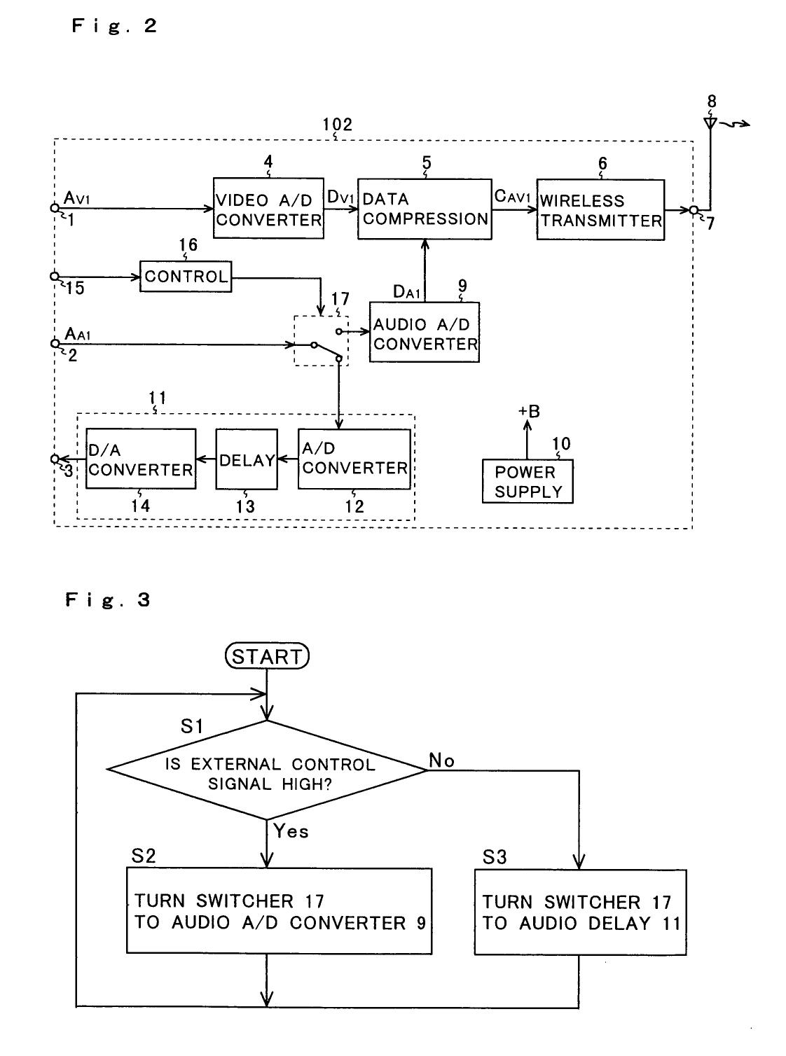

Next, the audio/video transmission system of a second embodiment of the invention will be described. The audio/video transmission system of the second embodiment includes an audio/video transmitter apparatus 102 as shown in FIG. 2, an antenna 8 as shown in FIG. 2, the same audio/video receiver apparatus as that provided in the audio/video transmission system of the first embodiment, and the antenna connected to that audio/video receiver apparatus. In FIG. 2, such circuit blocks as are found also in FIG. 1 are identified with the same reference numerals, and their explanations will not be repeated.

As compared with the audio/video transmitter apparatus 101 provided in the audio/video transmission system shown FIG. 1, the audio/video transmitter apparatus 102 is additionally provided with a control signal input terminal 15, a control circuit 16, and a switcher circuit 17.

The control signal input terminal 15 is connected to the input end of the control circuit 16, and the output end of the control circuit 16 is connected to the control terminal of the switcher circuit 17.

The audio input terminal 2 is connected to the movable contact of the switcher circuit 17. One fixed contact of the switcher circuit 17 is connected to the input end of the audio A/D converter circuit 9, and the other fixed contact of the switcher circuit 17 is connected to the input end of the A/D converter circuit 12.

The control circuit 16 controls the switcher circuit 17 according to a control signal (hereinafter referred to as the external control signal) fed in via the control signal input terminal 15. According to the output signal of the control circuit 16, the switcher circuit 17 switches whether to feed the analog audio signal A_{A1} fed in via the audio input terminal 2 to the audio A/D converter circuit 9 or to the A/D converter circuit 12.

FIG. 3 is a flow chart showing the operation of the control circuit 16 when it is realized with a microcomputer. In this embodiment, it is assumed that the external control signal is either logically high or low at a time.

First, the control circuit 16 checks whether the external control signal is high or not (step S1). If the external control signal is high (“Yes” in step S1), the flow proceeds to step S2. By contrast, if the external control signal is not high but low (“No” in step S1), the flow proceeds to step S3.

In step S2, the control circuit 16 controls the switcher circuit 17 so that the switcher circuit 17 feeds the analog audio signal A_{A1} fed in via the audio input terminal 2 to the audio A/D converter circuit 9. The flow then returns to step S1.

In step S3, the control circuit 16 controls the switcher circuit 17 so that the switcher circuit 17 feeds the analog audio signal A_{A1} fed in via the audio input terminal 2 to the A/D converter circuit 12 provided in the audio delay circuit 11. The flow then returns to step S1.

It should be understood that the external control signal described above as being either logically high or low at a time is merely an example of an external control signal usable as such, and that the present invention may be practiced in any other manner than specifically described above.

The audio/video transmission system of the second embodiment has, in addition to the advantages offered by the audio/video transmission system of the first embodiment described earlier, the following advantage. For example, in a case where speakers are connected via an amplifier to the audio output terminal 3 of the audio/video transmitter apparatus 102 and the external input terminals of a television monitor are connected to the video and audio output terminals of the audio/video receiver apparatus, the user, by controlling the control signal fed in via the control signal input terminal 15, can select either the speakers or television monitor as the device by which to output audio. This helps prevent the speakers and television monitor from outputting audio simultaneously.

Here, a single A/D converter circuit may be shared as the audio A/D converter circuit 9 and A/D converter circuit 12. In that case, the audio input terminal 2 is connected to the input end of the shared circuit, and the output end of the shared circuit is connected to the movable contact of the switcher circuit 17. Moreover, one fixed contact of the switcher circuit 17 is connected to the input end of the data compression circuit 5, and the other fixed contact of the switcher circuit 17 is connected to the input end of the delay circuit 13. Thus, according to the output signal of the control circuit 16, the switcher circuit 17 switches whether to feed the output signal of the shared circuit to the data compression circuit 5 or to the delay circuit 13.

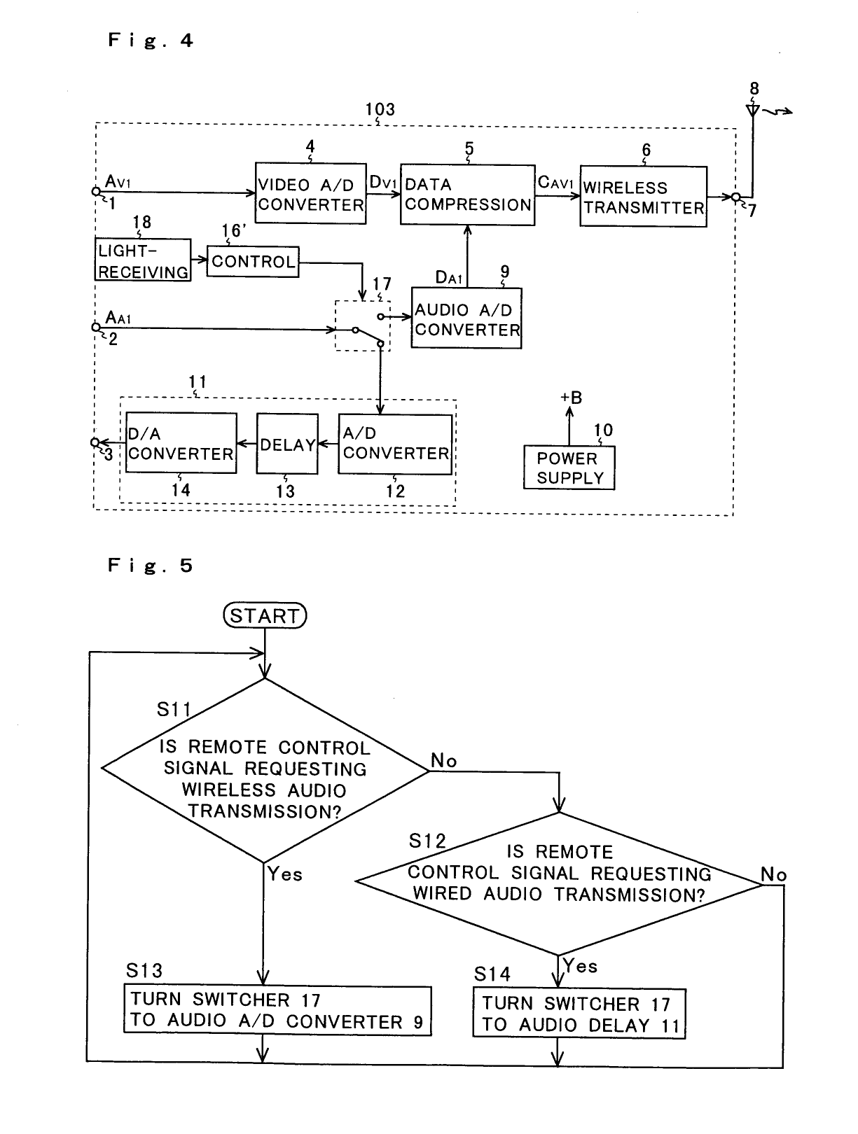

Next, the audio/video transmission system of a third embodiment of the invention will be described. The audio/video transmission system of the third embodiment includes an audio/video transmitter apparatus 103 as shown in FIG. 4, an antenna 8 as shown in FIG. 4, the same audio/video receiver apparatus as that provided in the audio/video transmission system of the first embodiment, and the antenna connected to that audio/video receiver apparatus. In FIG. 4, such circuit blocks as are found also in FIG. 2 are identified with the same reference numerals, and their explanations will not be repeated.

As compared with the audio/video transmitter apparatus 102 shown in FIG. 2, the audio/video transmitter apparatus 103 lacks the control signal input terminal 15 but is instead additionally provided with a light-receiving circuit 18, and moreover lacks the control circuit 16 but is instead provided with a control circuit 16′ that operates in a different manner than the control circuit 16. The light-receiving circuit 18 is connected to the input end of the control circuit 16′, and the output end of the control circuit 16′ is connected to the control terminal of the switcher circuit 17.

The light-receiving circuit 18 receives an infrared remote control signal (hereinafter referred to as the remote control signal) transmitted from a remote control transmitter (not illustrated), converts the received remote control signal into an electrical signal, and feeds the electrical signal to the control circuit 16′. According to the electrical signal output from the light-receiving circuit 18, the control circuit 16′ controls the switcher circuit 17.

FIG. 5 is a flow chart showing the operation of the control circuit 16′ when it is realized with a microcomputer.

First, on the basis of the electrical signal output from the light-receiving circuit 18, the control circuit 16′ checks whether the remote control signal is a signal requesting “wireless audio signal transmission” or not (step S11). If the remote control signal is a signal requesting “wireless audio signal transmission” (“Yes” in step S11), the flow proceeds to step S13. By contrast, if the remote control signal is not a signal requesting “wireless audio signal transmission” (“No” in step S11), the flow proceeds to step S12.

In step S12, on the basis of the electrical signal output from the light-receiving circuit 18, the control circuit 16′ checks whether the remote control signal is a signal requesting “wired audio signal transmission” or not (step S12). If the remote control signal is a signal requesting “wired audio signal transmission” (“Yes” in step S12), the flow proceeds to step S14. By contrast, if the remote control signal is not a signal requesting “wired audio signal transmission” (“No” in step S12), the flow returns to step S11.

In step S13, the control circuit 16′ controls the switcher circuit 17 so that the switcher circuit 17 feeds the analog audio signal A_{A1} fed in via the audio input terminal 2 to the audio A/D converter circuit 9. The flow then returns to step S11.

In step S14, the control circuit 16′ controls the switcher circuit 17 so that the switcher circuit 17 feeds the analog audio signal A_{A1} fed in via the audio input terminal 2 to the A/D converter circuit 12 provided in the audio delay circuit 11. The flow then returns to step S11.

It should be understood that the remote control signal described above as being a signal requesting “wireless audio signal transmission” at one time and a signal requesting “wired audio signal transmission” at another time is merely an example of a remote control signal usable as such, and that the present invention may be practiced in any other manner than specifically described above.

The audio/video transmission system of the third embodiment has, in addition to the advantages offered by the audio/video transmission system of the second embodiment described earlier, the following advantage. The user, by using a remote control transmitter, can select the device by which to output audio. This enhances usability.

Here, a single A/D converter circuit may be shared as the audio A/D converter circuit 9 and A/D converter circuit 12. In that case, the audio input terminal 2 is connected to the input end of the shared circuit, and the output end of the shared circuit is connected to the movable contact of the switcher circuit 17. Moreover, one fixed contact of the switcher circuit 17 is connected to the input end of the data compression circuit 5, and the other fixed contact of the switcher circuit 17 is connected to the input end of the delay circuit 13. Thus, according to the output signal of the control circuit 16′, the switcher circuit 17 switches whether to feed the output signal of the shared circuit to the data compression circuit 5 or to the delay circuit 13.

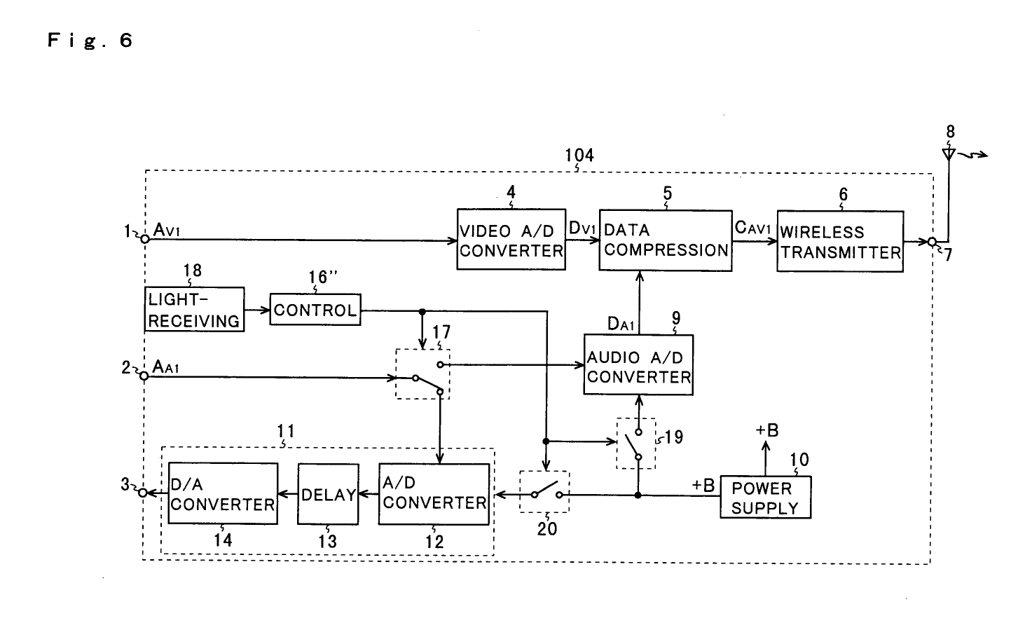

Next, the audio/video transmission system of a fourth embodiment of the invention will be described. The audio/video transmission system of the fourth embodiment includes an audio/video transmitter apparatus 104 as shown in FIG. 6, an antenna 8 as shown in FIG. 6, the same audio/video receiver apparatus as that provided in the audio/video transmission system of the first embodiment, and the antenna connected to that audio/video receiver apparatus. In FIG. 6, such circuit blocks as are found also in FIG. 4 are identified with the same reference numerals, and their explanations will not be repeated.

As compared with the audio/video transmitter apparatus 103 shown in FIG. 4, the audio/video transmitter apparatus 104 is additionally provided with switch circuits 19 and 20, and moreover lacks the control circuit 16′ but is instead provided with a control circuit 16″ that operates in a different manner than the control circuit 16′. The light-receiving circuit 18 is connected to the input end of the control circuit 16″, and the output end of the control circuit 16″ is connected to the control terminal of each of the switcher circuit 17 and switch circuits 19 and 20. The power supply circuit 10 is connected via the switch circuit 19 to the audio A/D converter circuit 9, and is connected via the switch circuit 20 to the individual circuits provided in the audio delay circuit 11. According to the electrical signal output from the light-receiving circuit 18, the control circuit 16″ controls the switcher circuit 17 and switch circuits 19 and 20.

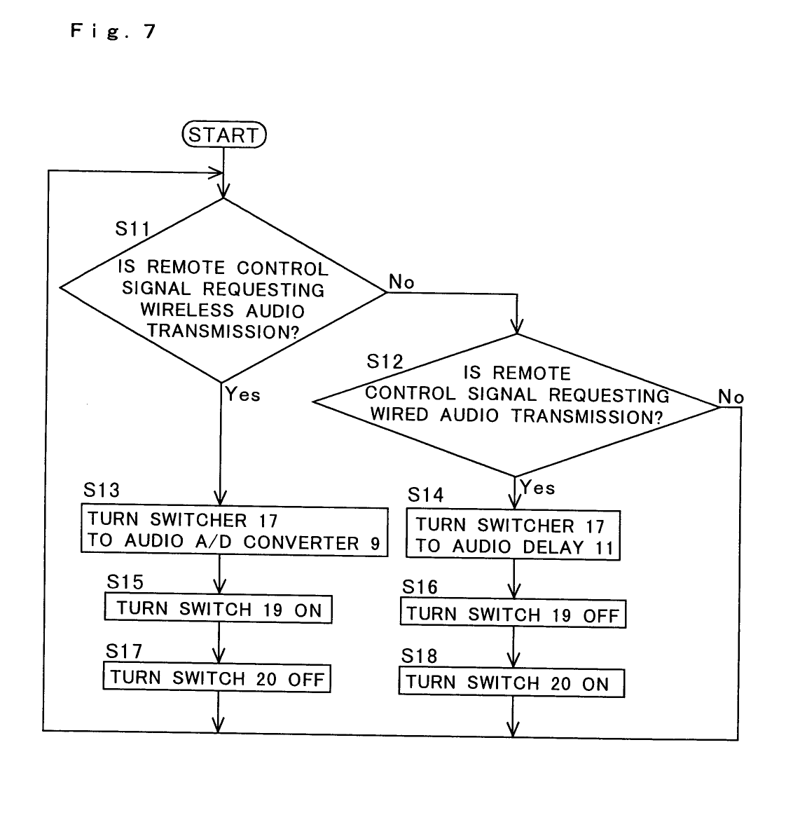

FIG. 7 is a flow chart showing the operation of the control circuit 16″ when it is realized with a microcomputer. In FIG. 7, such steps as are found also in FIG. 5 are identified with the same reference symbols.

First, on the basis of the electrical signal output from the light-receiving circuit 18, the control circuit 16″ checks whether the remote control signal is a signal requesting “wireless audio signal transmission” or not (step S11). If the remote control signal is a signal requesting “wireless audio signal transmission” (“Yes” in step S11), the flow proceeds to step S13. By contrast, if the remote control signal is not a signal requesting “wireless audio signal transmission” (“No” in step S11), the flow proceeds to step S12.

In step S12, on the basis of the electrical signal output from the light-receiving circuit 18, the control circuit 16″ checks whether the remote control signal is a signal requesting “wired audio signal transmission” or not (step S12). If the remote control signal is a signal requesting “wired audio signal transmission” (“Yes” in step S12), the flow proceeds to step S14. By contrast, if the remote control signal is not a signal requesting “wired audio signal transmission” (“No” in step S12), the flow returns to step S11.

In step S13, the control circuit 16″ controls the switcher circuit 17 so that the switcher circuit 17 feeds the analog audio signal A_{A1} fed in via the audio input terminal 2 to the audio A/D converter circuit 9. Thereafter, the control circuit 16″ turns the switch circuit 19 on (step S15), and then turns the switch circuit 20 off (step S17). The flow then returns to step S11.

In step S14, the control circuit 16″ controls the switcher circuit 17 so that the switcher circuit 17 feeds the analog audio signal A_{A1} fed in via the audio input terminal 2 to the A/D converter circuit 12 provided in the audio delay circuit 11. Thereafter, the control circuit 16″ turns the switch circuit 19 off (step S16), and then turns the switch circuit 20 on (step S18). The flow then returns to step S11.

It should be understood that the remote control signal described above as being a signal requesting “wireless audio signal transmission” at one time and a signal requesting “wired audio signal transmission” at another time is merely an example of a remote control signal usable as such, and that the present invention may be practiced in any other manner than specifically described above.

The audio/video transmission system of the fourth embodiment has, in addition to the advantages offered by the audio/video transmission system of the third embodiment described earlier, the following advantage. When the analog audio signal A_{A1} is not fed to the audio A/D converter circuit 9, the supply of electric power to the audio A/D converter circuit 9 can be turned off Likewise, when the analog audio signal A_{A1} is not fed to the audio delay circuit 11, the supply of electric power to the audio delay circuit 11 can be turned off. This makes it possible to reduce to zero the electric power consumed by the audio A/D converter circuit 9 and audio delay circuit 11 when they are in a stand-by state, and thereby save power.

Here, a single A/D converter circuit may be shared as the audio A/D converter circuit 9 and A/D converter circuit 12. In that case, the audio input terminal 2 is connected to the input end of the shared circuit, and the output end of the shared circuit is connected to the movable contact of the switcher circuit 17. Moreover, one fixed contact of the switcher circuit 17 is connected to the input end of the data compression circuit 5, and the other fixed contact of the switcher circuit 17 is connected to the input end of the delay circuit 13. Thus, according to the output signal of the control circuit 16″, the switcher circuit 17 switches whether to feed the output signal of the shared circuit to the data compression circuit 5 or to the delay circuit 13. Moreover, the switch circuit 19 is omitted, and the switch circuit 20 turns on and off the supply of electric power to the delay circuit 13 and D/A converter circuit 14.

In the first to fourth embodiments described above, an antenna is externally fitted to each of the audio/video transmitter and receiver apparatuses. It is, however, also possible to incorporate the antenna in each of the audio/video transmitter and receiver apparatuses.

In the first to fourth embodiments described above, the audio/video transmitter and receiver apparatuses achieve wireless communication between them by using a radio wave. It is, however, also possible to use any other wireless signal than a radio wave, for example an infrared signal.

The audio/video transmitter and receiver apparatuses may be provided with, instead of the power supply circuit that converts an alternating-current voltage into a predetermined direct-current voltage, a DC terminal by way of which a predetermined direct-current voltage is fed in.

In the second to fourth embodiments described above, the control circuit controls the switcher circuit and/or switch circuits according to a control signal fed from outside. It is, however, also possible to provide the audio/video transmitter apparatus with a detection circuit for detecting whether an external appliance is connected to the audio output terminal 3 or not so that the control circuit controls the switcher circuit and/or switch circuits according to the output signal of the detection circuit.

What is claimed is:

1. An audio/video transmitter apparatus comprising:
a video A/D converter circuit for converting an input analog video signal into a digital video signal;
an audio A/D converter circuit for converting an input analog audio signal into a digital audio signal;
a data compression circuit for performing data compression on the digital video and audio signals;
a wireless transmitter circuit for modulating a compressed audio/video signal output from the data compression circuit; and
an audio delay circuit for outputting the input analog audio signal with a predetermined delay time.

2. The audio/video transmitter apparatus according to claim 1,
wherein the audio delay circuit comprises:
an A/D converter circuit for converting the input analog audio signal into a digital audio signal;
a delay circuit for delaying by the predetermined delay time the digital audio signal output from the A/D converter circuit; and
a D/A converter circuit for converting the digital audio signal output from the delay circuit into an analog audio signal.

3. The audio/video transmitter apparatus according to claim 2, further comprising:
a switcher,
wherein the switcher selects one of the audio A/D converter circuit and the audio delay circuit so that the input analog audio signal is fed only to the selected one of the audio A/D converter circuit and the audio delay circuit and not to the other.

4. The audio/video transmitter apparatus according to claim 3, further comprising:
a controller,
wherein the controller controls the switcher according to a control signal fed from outside.

5. The audio/video transmitter apparatus according to claim 3, further comprising:
a first switch; and
a first switch controller,
wherein the first switch turns on and off supply of electric power to the audio A/D converter circuit, and
wherein, when the switcher selects the audio A/D converter circuit, the first switch controller controls the first switch so as to turn on supply of electric power to the audio A/D converter circuit and, when the switcher selects the audio delay circuit, the first switch controller controls the first switch so as to turn off supply of electric power to the audio A/D converter circuit.

6. The audio/video transmitter apparatus according to claim 3, further comprising:
a second switch; and
a second switch controller,
wherein the second switch turns on and off supply of electric power to the audio delay circuit, and
wherein, when the switcher selects the audio delay circuit, the second switch controller controls the second switch so as to turn on supply of electric power to the audio delay circuit and, when the switcher selects the audio A/D converter circuit, the second switch controller controls the second switch so as to turn off supply of electric power to the audio delay circuit.

7. The audio/video transmitter apparatus according to claim 4, further comprising:
a light-receiving circuit,
wherein the light-receiving circuit receives the control signal in a form of an infrared remote control signal, converts the received infrared remote control signal into an electrical signal, and feeds the electrical signal to the controller.

8. The audio/video transmitter apparatus according to claim 4, further comprising:
a first switch;
a first switch controller,
a second switch; and
a second switch controller,
wherein the first switch turns on and off supply of electric power to the audio A/D converter circuit,
wherein, when the switcher selects the audio A/D converter circuit, the first switch controller controls the first switch so as to turn on supply of electric power to the audio A/D converter circuit and, when the switcher selects the audio delay circuit, the first switch controller controls the first switch so as to turn off supply of electric power to the audio A/D converter circuit,
wherein the second switch turns on and off supply of electric power to the audio delay circuit, and
wherein, when the switcher selects the audio delay circuit, the second switch controller controls the second switch so as to turn on supply of electric power to the audio delay circuit and, when the switcher selects the audio A/D converter circuit, the second switch controller controls the second switch so as to turn off supply of electric power to the audio delay circuit.

9. The audio/video transmitter apparatus according to claim 7, further comprising:
a first switch;
a first switch controller,
a second switch; and
a second switch controller,
wherein the first switch turns on and off supply of electric power to the audio A/D converter circuit,
wherein, when the switcher selects the audio A/D converter circuit, the first switch controller controls the first switch so as to turn on supply of electric power to the audio A/D converter circuit and, when the switcher selects the audio delay circuit, the first switch controller controls the first switch so as to turn off supply of electric power to the audio A/D converter circuit,
wherein the second switch turns on and off supply of electric power to the audio delay circuit, and
wherein, when the switcher selects the audio delay circuit, the second switch controller controls the second switch so as to turn on supply of electric power to the audio delay circuit and, when the switcher selects the audio A/D converter circuit, the second switch controller controls the second switch so as to turn off supply of electric power to the audio delay circuit.

10. An audio/video transmission system comprising:
an audio/video transmitter apparatus;
a wireless signal transmitter for transmitting a wireless signal according to a signal output from a wireless transmitter circuit provided in the audio/video transmitter apparatus;
a wireless signal receiver for receiving the wireless signal transmitted from the wireless signal transmitter to output a signal according to the received wireless signal; and
an audio/video receiver apparatus including:
a wireless receiver circuit for demodulating a signal output from the wireless signal receiver to output a compressed audio/video signal; and
a data decompression circuit for performing data decompression on the compressed audio/video signal output from the wireless receiver circuit,
wherein the audio/video transmitter apparatus comprises:
a video A/D converter circuit for converting an input analog video signal into a digital video signal;
an audio A/D converter circuit for converting an input analog audio signal into a digital audio signal;
a data compression circuit for performing data compression on the digital video and audio signals;
a wireless transmitter circuit for modulating a compressed audio/video signal output from the data compression circuit; and
an audio delay circuit for outputting the input analog audio signal with a predetermined delay time.

11. The audio/video transmission system according to claim 10,
wherein the predetermined delay time produced by the audio delay circuit provided in the audio/video transmitter apparatus is substantially equal to a time required for signal processing performed by the data compression circuit provided in the audio/video transmitter apparatus and by the data decompression circuit provided in the audio/video receiver apparatus.

12. The audio/video transmission system according to claim 10,
wherein the audio delay circuit comprises:
an A/D converter circuit for converting the input analog audio signal into a digital audio signal;
a delay circuit for delaying by the predetermined delay time the digital audio signal output from the A/D converter circuit; and
a D/A converter circuit for converting the digital audio signal output from the delay circuit into an analog audio signal.

13. The audio/video transmission system according to claim 12, further comprising:
a switcher,
wherein the switcher selects one of the audio A/D converter circuit and the audio delay circuit so that the input analog audio signal is fed only to the selected one of the audio A/D converter circuit and the audio delay circuit and not to the other.

14. The audio/video transmission system according to claim 13, further comprising:
a controller,
wherein the controller controls the switcher according to a control signal fed from outside.

15. The audio/video transmission system according to claim 13, further comprising:
a first switch; and
a first switch controller,
wherein the first switch turns on and off supply of electric power to the audio A/D converter circuit, and
wherein, when the switcher selects the audio A/D converter circuit, the first switch controller controls the first switch so as to turn on supply of electric power to the audio A/D converter circuit and, when the switcher selects the audio delay circuit, the first switch controller controls the first switch so as to turn off supply of electric power to the audio AID converter circuit.

16. The audio/video transmission system according to claim 13, further comprising:
a second switch; and
a second switch controller,
wherein the second switch turns on and off supply of electric power to the audio delay circuit, and
wherein, when the switcher selects the audio delay circuit, the second switch controller controls the second switch so as to turn on supply of electric power to the audio delay circuit and, when the switcher selects the audio A/D converter circuit, the second switch controller controls the second switch so as to turn off supply of electric power to the audio delay circuit.

17. The audio/video transmission system according to claim 14, further comprising:
a light-receiving circuit,
wherein the light-receiving circuit receives the control signal in a form of an infrared remote control signal, converts the received infrared remote control signal into an electrical signal, and feeds the electrical signal to the controller.

18. The audio/video transmission system according to claim 14, further comprising:
a first switch;
a first switch controller,
a second switch; and
a second switch controller,
wherein the first switch turns on and off supply of electric power to the audio A/D converter circuit,
wherein, when the switcher selects the audio A/D converter circuit, the first switch controller controls the first switch so as to turn on supply of electric power to the audio A/D converter circuit and, when the switcher selects the audio delay circuit, the first switch controller controls the first switch so as to turn off supply of electric power to the audio A/D converter circuit,
wherein the second switch turns on and off supply of electric power to the audio delay circuit, and
wherein, when the switcher selects the audio delay circuit, the second switch controller controls the second switch so as to turn on supply of electric power to the audio delay circuit and, when the switcher selects the audio A/D converter circuit, the second switch controller controls the second switch so as to turn off supply of electric power to the audio delay circuit.

19. The audio/video transmission system according to claim 17, further comprising:
a first switch;
a first switch controller,
a second switch; and
a second switch controller,
wherein the first switch turns on and off supply of electric power to the audio A/D converter circuit,
wherein, when the switcher selects the audio A/D converter circuit, the first switch controller controls the first switch so as to turn on supply of electric power to the audio A/D converter circuit and, when the switcher selects the audio delay circuit, the first switch controller controls the first switch so as to turn off supply of electric power to the audio A/D converter circuit,
wherein the second switch turns on and off supply of electric power to the audio delay circuit, and
wherein, when the switcher selects the audio delay circuit, the second switch controller controls the second switch so as to turn on supply of electric power to the audio delay circuit and, when the switcher selects the audio A/D converter circuit, the second switch controller controls the second switch so as to turn off supply of electric power to the audio delay circuit.

20. The audio/video transmission system according to claim 19,
wherein the predetermined delay time produced by the audio delay circuit provided in the audio/video transmitter apparatus is substantially equal to a time required for signal processing performed by the data compression circuit provided in the audio/video transmitter apparatus and by the data decompression circuit provided in the audio/video receiver apparatus.
